(19) United States
(12) Patent Application Publication
(10) Pub. No.: US 2007/0062676 A1
(43) Pub. Date: Mar. 22, 2007

(54) Heat sink module

(75) Inventor: Pei-Chih Yao, Taipei (TW)

Correspondence Address: BACON & THOMAS, PLLC, 625 SLATERS LANE, FOURTH FLOOR, ALEXANDRIA, VA, 22314, US

(73) Assignee: GRAND POWER SOURCES INC., TAIPEI (TW)

(21) Appl. No.: 11/229,509

(22) Filed: Sep. 20, 2005

(51) Int. Cl. H05K 7/20

(52) U.S. Cl. 165/104.33; 165/80.3; 361/705

(57) ABSTRACT

A heat sink module includes a base having a metal heat dissipating fin set, and the base includes a planar base member comprised of a plurality of graphite layers, and said planar base member embeds a vertical insert having a high thermal conductivity, and the insert comprises a graphite compound disposed vertically with the base member for conducting heat or an isotropic thermal conductive metal compound, or a thermal conductive material compound that produces a phase change by heat, and the base member includes a thermal conductive frame having an isotropic high thermal conductivity and disposed at the periphery, and the thermal conductive frame and the base member are combined to form a heat dissipating base. When the heat sink module is in use, the area proximate to the inserts is attached to the core of a heat source core, so that the inserts can absorb and conduct the heat produced by the heat source quickly. Since the graphite layer is anisotropic when conducting heat, therefore the heat is conducted from the periphery to the thermal conductive frame by the horizontal graphite layer when the heat is conducted to the insert, and then the heat is dissipated to the outside via the thermal conductive frame quickly by the heat dissipating fin.

### BACKGROUND OF THE INVENTION

1. Field of the Invention

The present invention relates to a heat sink module, and more particularly to a heat sink module including a base member made of a graphite layer with a high thermal conductivity along a planar direction, an insert embedded vertically onto the planar base member and having a high thermal conductivity, and a thermal conductive frame having an isotropic high thermal conductivity, such that the heat can be conducted quickly from the heat source from the insert through the base member, and the heat is dispersed from the conductive frame to the periphery and the outside, and thus the heat will not remain on the heat source.

2. Description of the Related Art

In recent years, electronic products tend to be packed in a high density and developed with multifunction, so that the heat dissipating issue becomes a serious problem. If electronic components do not have a proper heat dissipating policy, then the performance cannot be maximized, or in a more serious case, the electronic products will not be stable due to the sudden increase of temperature inside the machine.

To suppress the rise of the temperature of the electronic components in an electronic product, a high thermal conductive metal heat sink made of copper or aluminum is used for dissipating the heat produced by the electronic components from the surface according to the temperature difference of the heat and the external air.

Regardless of the metal heat sink modules, the volume of the heat sink will be increased as the area of the electronic components and the speed of producing heat are increased. However, an increase of volume will increase the weight. More particularly, electronic products tend to be light, thin, short, and compact, and it is obvious that the internal space provided by electronic products for dissipating heat is insufficient. The increase in weight of the heat sink may press and damage electronic components or have other adverse effects.

Referring to FIG. 1, graphite used as a heat dissipating material was disclosed in U.S. Pat. No. 6,758,263, the invention comprises a graphite planar element 100, and the planar element 100 has a high thermal conductivity and is installed parallel to the heat source, and the planar element 100 includes a cavity 101, such that a high thermal conductivity insert 110 is received in the cavity 101, and the insert 110 could be made of copper, and a plurality of heat dissipating fins 120 parallel with each other are embedded into the planar element 100.

Although the foregoing device can use graphite instead of metal as a planar element to reduce the weight of the heat dissipating planar element, and the graphite has a high thermal conductivity, yet the graphite is anisotropic when conducting heat. If the planar element 100 absorbs the heat conducted from the insert 110, the planar element 100 has a high thermal conductivity parallel to the heat source only and has no high thermal conductivity passage to conduct the heat to the heat dissipating fin 120. Therefore, the heat cannot be dissipated to the outside quickly by the heat dissipating fins. As a result, the heat remains at the planar element 100 and causes damages to the electronic component or even a system crash.

### SUMMARY OF THE INVENTION

In view of the shortcomings of the prior art, the inventor of the present invention based on years of experience to conduct extensive researches and experiments, and finally invented a heat sink module capable of conducting heat and dissipating heat to the outside quickly as to enhance the heat dissipating effect.

Therefore, it is a primary objective of the present invention to provide a heat sink module comprising a base, and the base comprises a base member and a thermal conductive frame. The base member comprises a plurality of graphite layers with a plane having a high thermal conductivity property, and the base member includes an insert received at an appropriate position of a cavity. The insert is comprised of a graphite compound conducting heat in a direction perpendicular to the base member, an isotropic thermal conductive metal compound, a thermal conductive composite that its thermal conductive filler produces a phase change due to heat, or a combination of the abovementioned composites. Further, the base member is closely sealed by a thermal conductive frame, and the base has a heat dissipating fin set, such that when the heat sink module is in use, the inserts are attached directly onto the core of a heat source to conduct heat from the inserts. When the inserts are conducting heat, the heat is conducted from the base at the periphery of the insert along its plane, and then from the base member to the thermal conductive frame, and finally dissipated to the outside via fin set in a quick manner. Therefore, the invention not only reduces the weight of the whole heat sink module by using a thermal conductive material such as a graphite composite to make the base, but also overcomes the shortcoming of having heat remained on the base.

Another objective of the present invention is to provide a heat sink module, and the base member of the base is substantially in a stairway shape, and the corresponding thermal conductive frame also has stairway shaped protrusions, such that the protrusions of the thermal conductive frame can be embedded closely onto different graphite layers of the base member, and thus the thermal conductive frame and the base member can be coupled closely together.

A further objective of the present invention is to provide a heat sink module, and its insert is made by a coil sheet, a lump member of a slab, a three-dimensional skeleton structure filled with an isotropic thermal conductive material, or a lump member of a phase-change composite.

### BRIEF DESCRIPTION OF THE DRAWINGS

The objective, shape, structure, device, characteristic and performance of the present invention will become apparent in the following detailed description of the preferred embodiments with reference to the accompanying drawings, in which:

FIG. 1 is a schematic view of a prior art device;

FIG. 2 is a perspective view of a preferred embodiment of the present invention;

FIG. 3 is an exploded view of a preferred embodiment of the present invention;

FIG. 4 is a top view of a preferred embodiment of the present invention;

FIG. 5 is a cross-sectional view of a first preferred embodiment of the present invention;

FIG. 6 is a cross-sectional view of a second preferred embodiment of the present invention;

FIG. 7 is a schematic view of a third preferred embodiment of the present invention;

FIG. 8 is a schematic view of a fourth preferred embodiment of the present invention;

FIG. 9 is a schematic view of a fifth preferred embodiment of the present invention; and

FIG. 10 is a cross-sectional view of a sixth preferred embodiment of the present invention.

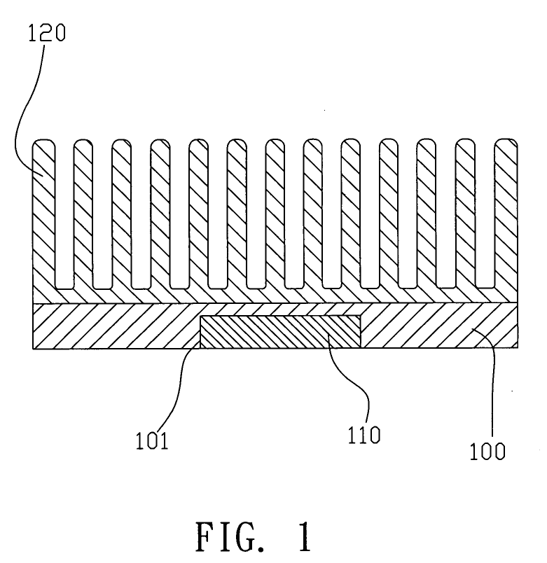

### DETAILED DESCRIPTION OF THE PREFERRED EMBODIMENTS

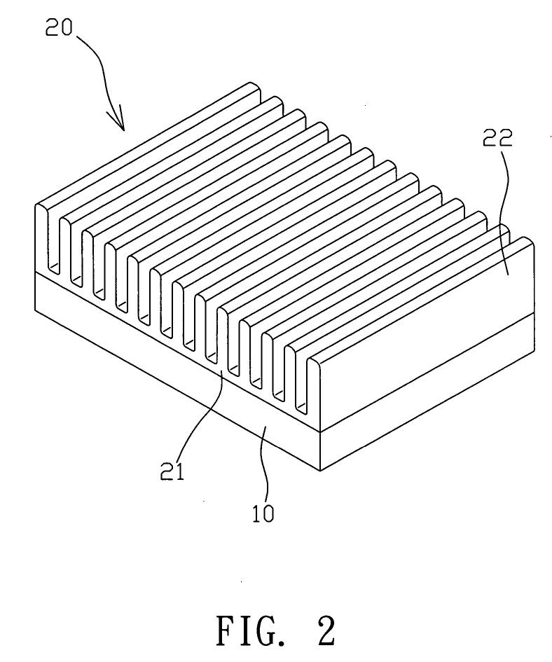

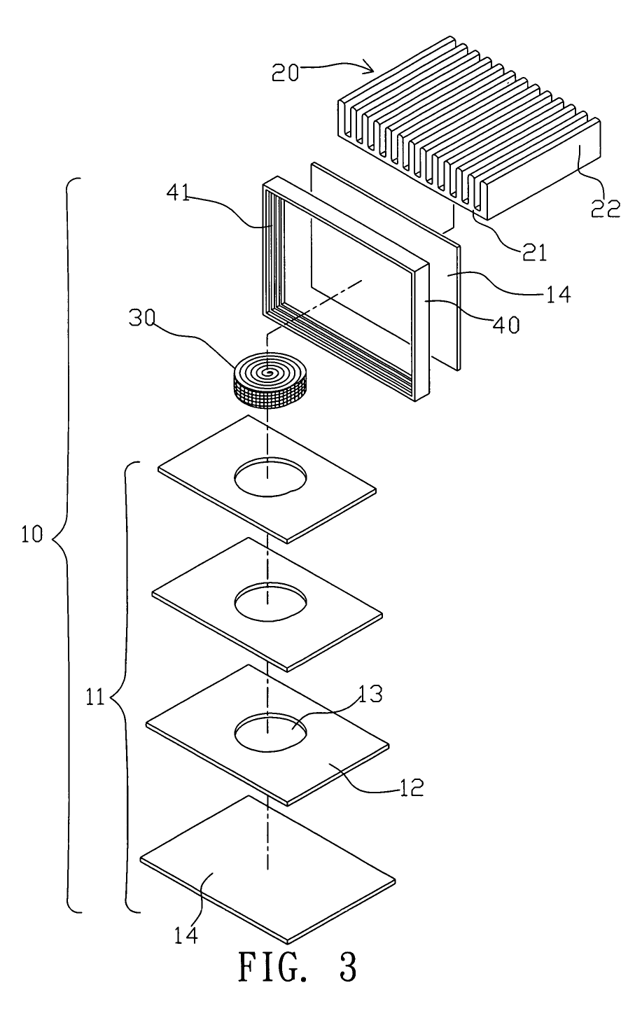

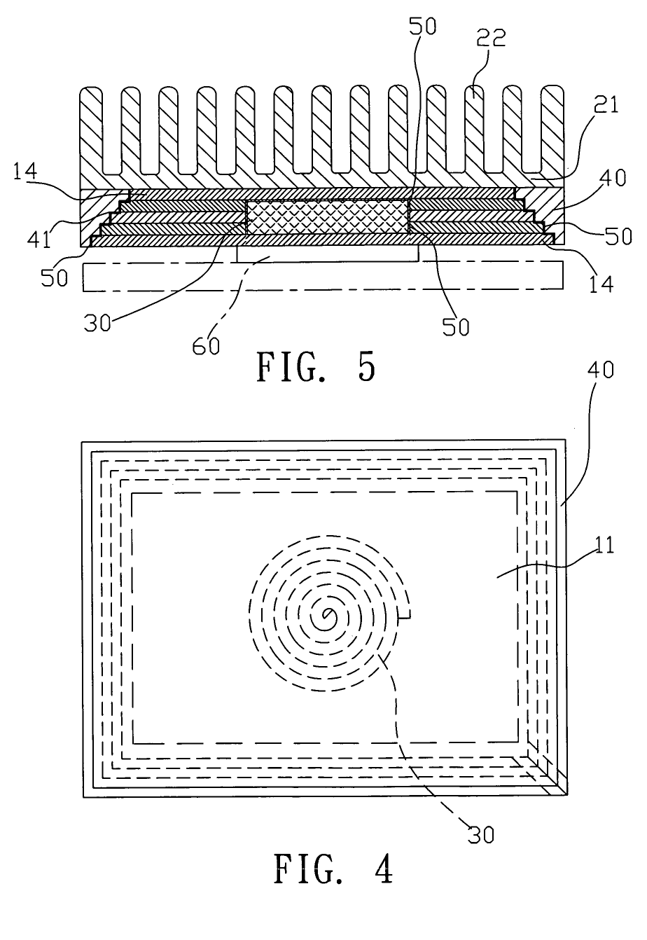

Referring to FIGS. 2 to 5 for the heat sink module of a preferred embodiment of the present invention, a base 10 comprises a heat dissipating fin set 20 thereon, and the heat dissipating fin set 20 includes a bottom 21 thereon, which is a slab for this embodiment, and the bottom 21 includes a plurality of fins 22 arranged neatly with each other.

The base 10 comprises a base member 11 and a hollow thermal conductive frame 40, and the base member 11 comprises a plurality of graphite layers 12 having a high thermal conductivity on its planar direction, and the area of the graphite layers 12 becomes increasingly smaller from the bottom to the top like a stairway shape, and the base member 11 has a cavity 13 disposed at an appropriate position for penetrating all graphite layers 12, and an insert 30 is received in the cavity 13. The insert 30 of this preferred embodiment is a coiled graphite sheet filled with a phase-change thermal conductive material (however, the persons skilled in the art can substitute this material by an isotropic thermal conductive metal compound or a thermal conductive composite that its thermal conductive filler produces a phase change due to heat), and the insert 30 attaches its cross-section capable of conducting heat quickly onto a heat source and perpendicular to the base member 11, and the insert 30 and the cavity 13 are coated with a thermal glue, solder (or paste) 50. The thermal glue, solder (or paste) 50 will be melted by heat of a high temperature and will produce a phase change, and thus will seal the insert 30 and the base member 11 closely with each other.

Further, the base member 11 has a hollow thermal conductive frame 40 sheathed onto the periphery of the base member 11, and the thermal conductive frame 40 is a copper alloy frame, and the thermal conductive frame 40 includes a plurality of protrusions 41 arranged in a stairway shape. The protrusions 41 can be embedded into different graphite layers 12 in the base member 11. The thermal glue, solder (or paste) 50 capable of having a phase change is coated between the protrusions 41 and the base member 11 to closely couple the thermal conductive frame 40 and the periphery of the base member 11 together.

Further, the thermal conductive frame 40 installs a thermal conductive plate 14 disposed at the top, the bottom, or the upper or lower opening of the thermal conductive frame 40 for installing the base member 11 onto the thermal conductive frame 40 and securing the connection of thermal conductive frame 40 with the bottom layer components 11.

Referring to FIG. 5 for the use of the heat sink module, the heat sink module of the present invention is attached directly onto a heat generating processor 60, such that the insert 30 can be attached directly onto the core of the heat source of the heat generating processor 60 to conduct the heat to the outside along the inserting direction of the insert 30. When the insert 30 conducts heat to the heat dissipating fin set 20, the insert 30 also conducts the heat to the periphery of the base member 11, and the base member 11 conducts the heat along its planar direction, and then from the base member 11 to the thermal conductive frame 40, and finally dissipated from the heat dissipating fin set 20 to the outside in a quick manner. The invention not only reduces the overall weight of the heat sink module by using a graphite thermal conductive composite to make the base member 11 and the insert 30, but also overcomes the shortcomings of having the heat remained on the base 10.

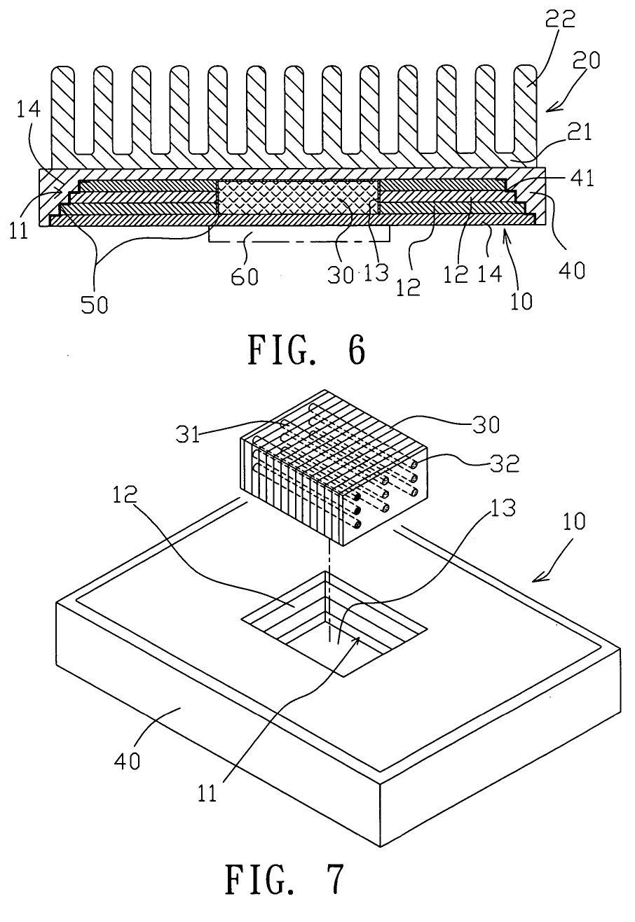

Referring to FIG. 6 for the second preferred embodiment of the present invention, the base 10 installs a heat dissipating fin set 20, and the heat dissipating fin set 20 includes a bottom 21, and the bottom 21 includes a plurality of fins 22 arranged neatly with each other.

The base 10 comprises a base member 11 and a thermal conductive frame 40, and the base member 11 comprises a plurality of graphite layers 12 having a high thermal conductivity property on their planar direction, and base member 11 has a cavity 13 disposed at an appropriate position for penetrating all graphite layers 12, and an insert 30 is received in the cavity 13. The insert 30 of this preferred embodiment is a coiled graphite sheet filled with a phase-change thermal conductive material (however, the persons skilled in the art can substitute this material by an isotropic thermal conductive metal compound or a thermal conductive composite that its thermal conductive filler produces a phase change due to heat), and the insert 30 attaches its cross-section capable of conducting heat quickly onto a heat source and perpendicular to the base member 11, and the insert 30 and the cavity 13 are coated with a thermal glue, solder (or paste) 50. The thermal glue, solder (or paste) 50 will be melted by heat of a high temperature and will produce a phase change, and thus sealing the insert 30 and the base member 11 closely with each other.

Further, the periphery of the bottom layer 10 is sealed by a surface adjacent to the heat dissipating fin set 20, and an n-shaped thermal conductive frame 40 of this preferred embodiment is a copper alloy frame, and the thermal conductive frame 40 includes a plurality of stairway shaped protrusions 41 therein, and these protrusions 41 are embedded into different graphite layers 12 in the base member 11. Further, a thermal conductive glue, solder (or paste) 50 capable of having a phase change is coated between the protrusions 41 and the base member 11 to securely connect the thermal conductive frame 40 with the periphery of the base member 11.

Further, a thermal conductive plate 14 is attached onto the opening of the thermal conductive frame 40 for placing the bottom layer components 11 into the thermal conductive frame 40 and reinforcing the heat conduction and connection between the thermal conductive frame 40 and the processor 60.

Referring to FIG. 7 for the third preferred embodiment of the present invention, the base 10 comprises a base member 11 and a thermal conductive frame 40, and the base 10 includes a cavity 13, and an insert is received in the cavity 13. The insert 30 of this preferred embodiment comprises a plurality of vertical sheet graphite layers, and the insert 30 includes a plurality of penetrating hole grooves 31, and each hole groove 31 includes a metal plug body 32 for strengthening the heat conduction effect of the insert 30 along the inserting direction of the metal plug body 32. When the heat sink module is in use, a cross-section of the insert 30 made of a graphite material having a high thermal conductivity and embedded in the base is placed onto a heat source (not shown in the figure). Therefore, the heat is conducted by the vertical sheet graphite layer of the insert 30 having an anisotropic thermal conduction property and the metal plug body 32 having an isotropic thermal conductivity property from the base member 11 and the thermal conductive frame 40 to the outside.

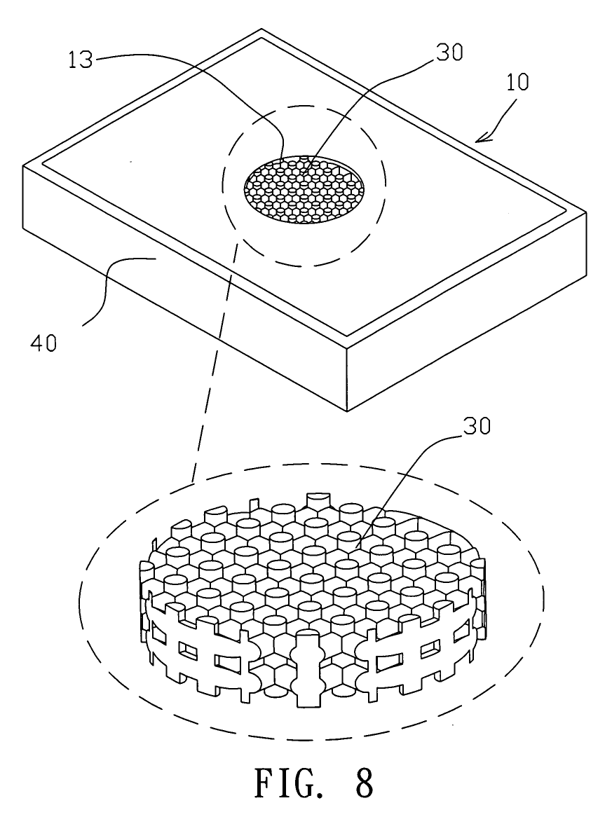

Referring to FIG. 8 for the fourth preferred embodiment of the present invention, the base 10 comprises a base member 11 and a thermal conductive frame 40, and the base 10 includes a cavity 13, and the cavity 13 receives an insert 30. The insert 30 of this embodiment is a three-dimensional skeleton structure made of graphite or an alloy compound material, and the structure is filled with an isotropic thermal conductive material. Although the graphite material has an anisotropic thermal conduction property, the three-dimensional skeleton structure composite insert can achieve a quick isotropic thermal conduction for conducting the heat to the outside. While the heat is being conducted to the outside, the insert 30 conducts the heat to each graphite layer of the base member 11, and the heat is conducted to the outside through the quick planar thermal conduction of each graphite layer and thermal conductive frame.

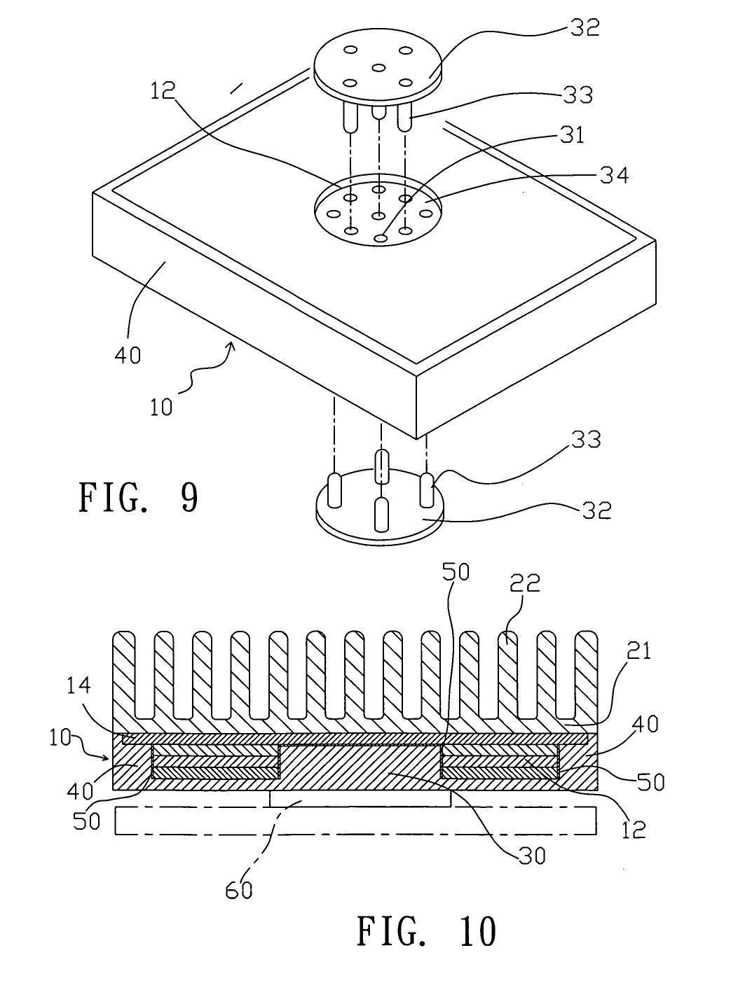

Referring to FIG. 9 for the fifth preferred embodiment of the present invention, the base 10 comprises a base member 11 and a thermal conductive frame 40, and the base member 11 of the base 10 includes recessions 34 disposed upward or downward, and the recessions 34 include a plurality of penetrating hole grooves 31, and the recessions 34 are in a circular, a square or any other shape. The recessions 34 can receive an insert 30, and the insert 30 is a metal plug body 32, and the metal plug body 32 includes a plurality of outwardly protruded pin bodies 33, and these pin bodies 33 tightly pass through the hole groove 31 to strengthen the heat conduction effect of the insert 30 along the insertion direction of the pin bodies 33, and the metal plug body 32 and the base member 11 are perpendicular with each other and placed onto the heat source. When the heat is conducted to the outside, the pin body 33 of the metal plug body 32 conducts the heat from the heat source to each graphite layer of the base member 11, and uses the high thermal conductivity of each graphite layer to conduct the heat from the thermal conductive frame 40 to the outside.

Referring to FIG. 10 for the sixth preferred embodiment of the present invention, the base 10 comprises a base member 11 and a thermal conductive frame 40, and the base 10 includes a cavity 13 for receiving an insert 30, and the insert 30 and the thermal conductive frame 40 are integrally coupled. The thermal conductive frame of this embodiment is made of a copper alloy. When the heat sink module is in use, the base 10 is placed onto the heat source. If the heat is conducted to the outside, the heat is conducted from the insert 30 to each graphite layer of the base member 11, and then the high thermal conductivity of each graphite layer is used to conduct the heat to the outside.

In summation of the above description, the present invention herein complies with the patent application requirements and is submitted for patent application. However, the description and its accompanied drawings are used for describing preferred embodiments of the present invention, and it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

1. A heat sink module comprising:
a base;
a base member, being disposed on said base and comprised of a plurality of graphite layers having a high thermal conductivity along its planar direction;
a thermal conductive frame, being embedded on the periphery of said base member; an insert, being embedded in said base member and said insert being a material with a high thermal conductivity;
such that when said heat sink module is in use, said insert is attached directly to a position proximate to a core of a heat source, and heat is conducted along the embedding direction of said insert, and when said insert conducts heat, the heat is conducted from said base member along the periphery of said insert and extended to its plane and then from said base member to said thermal conductive frame, so as to quickly dissipate the heat to the outside and the heat will not remain on said base.

2. The heat sink module of claim 1, wherein said insert is disposed perpendicular to said base member and comprised of a graphite composite material having a high thermal conductivity.

3. The heat sink module of claim 1, wherein said insert comprises a plurality of vertical sheet graphite composite layers, and said insert comprises a plurality of penetrating hole grooves, and said hole groove comprises a metal rod passing therein for reinforcing the thermal conductive effect of said insert along the passing direction of said metal rod.

4. The heat sink module of claim 1, wherein said insert is a metal plug and said base member comprises a plurality of penetrating hole grooves, and said metal plug comprises a plurality of outwardly protruded pins, and said pins pass through said hole grooves on said base member for reinforcing the heat conductive effect of said insert along the passing direction of said pins.

5. The heat sink module of claim 1, wherein said insert is an isotropic metal thermal conductive composite.

6. The heat sink module of claim 1, wherein said insert is a thermal conductive composite that its thermal conductive filler produces a phase change due to heat.

7. The heat sink module of claim 1, wherein said insert comprises a coiled graphite sheet filled with a phase-change thermal conductive material.

8. The heat sink module of claim 1, wherein said insert is a three-dimensional porous skeleton structure filled with an isotropic thermal conductive material.

9. The heat sink module of claim 1, wherein said insert is integrally coupled with said thermal conductive frame.

10. The heat sink module of claim 1, wherein said thermal conductive frame is a copper alloy frame.

11. The heat sink module of claim 1, wherein said thermal conductive frame has a closed end and a corresponding open end to form an n-shape.

12. The heat sink module of claim 1, wherein said thermal conductive frame is an aluminum alloy frame.

13. The heat sink module of claim 1, wherein said graphite layers of said base member are arranged in a stairway shape, and a plurality of protrusions is disposed in said corresponding thermal conductive frame and in a stairway shape, such that said protrusions of said thermal conductive frame are embedded into different graphite layers of said bottom layer to couple said thermal conductive frame with said bottom layer.
